(19) United States
(12) Patent Application Publication
(10) Pub. No.: US 2009/0184395 A1
(43) Pub. Date: Jul. 23, 2009

(54) INPUT/OUTPUT (I/O) BUFFER

(76) Inventor: Che-Yuan Jao, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/018,206

(22) Filed: Jan. 23, 2008

(51) Int. Cl. H01L 29/86; H02H 3/08

(52) U.S. Cl. 257/536; 361/93.7; 257/E29.325

(57) ABSTRACT

An I/O buffer including an I/O circuit, a pad and a pulling resistant device. The I/O circuit is for inputting or outputting a signal. The pulling resistant device has a plurality of resistant elements electrically connected between the I/O circuit and the pad, for forming a resistance value.

### BACKGROUND OF THE INVENTION

1. Field of the Invention

The present invention relates to an I/O buffer. Particularly, it relates to an I/O buffer having a pulling resistant device.

2. Description of the Prior Art

FIG. 1 is a schematic diagram illustrating a prior art I/O buffer 100 having an ESD protection circuit 105. As shown in FIG. 1, the I/O buffer 100 comprises an I/O circuit 101 and a contact pad 103. As known by persons skilled in the art, the I/O buffer 100 includes an ESD protection circuit 105 and a resistor 107 for pulling up or pulling down the voltage. Normally, the ESD protection circuit 105 can absorb an ESD pulse while the ESD pulse is induced.

Some applications of the I/O buffer, such as being implemented in the interface circuits, require more linear pull-up or pull-down driving characteristics, and therefore the resistance value of the resistor 107 may be added to obtain linear response. Over the course of the circuit usage, the resistor 107 with such large resistance value will easily endure considerable power dissipation (P=I²R) and will tend to break. Additionally, the ESD protection circuit 105 increases the occupied area of the I/O buffer 100.

FIG. 2 illustrates the top view of the prior art I/O buffer 200 layout having an ESD protection circuit. The I/O buffer 200 includes an active circuit region 201 such as an I/O buffer, a metal region 203, a resistor region 205, a silicide block region 207 and an ESD protection circuit region 209. As shown in FIG. 2, the ESD protection circuit region 209 requires a large area, and thus the total area of the circuit increases as well. A new invention is therefore needed to solve these problems.

### SUMMARY OF THE INVENTION

Therefore, one objective of the present invention is to provide an I/O buffer that can increase the longevity and reliability of the pulling resistant device thereof.

Another objective of the present invention is to provide an I/O buffer which can reduce the loading of the ESD protection circuit while the resistant value of the pulling resistant device is large.

One embodiment of the present invention discloses an I/O buffer, which comprises an I/O circuit, a pad and a pulling resistant device. The I/O circuit is for inputting or outputting a signal. The pulling resistant device has a plurality of resistant elements electrically connected between the I/O circuit and the pad, for forming a resistance value.

According to one embodiment, the semiconductor structure of an I/O buffer comprises: a substrate; an active circuit, formed on the substrate; a silicon oxide layer on the substrate; a patterned poly-silicon layer on the silicon oxide layer, the patterned poly-silicon layer having a first part and a second part; a patterned silicide layer on the patterned poly-silicon layer to expose at least part of the patterned poly-silicon layer; a dielectric layer on the patterned poly-silicon layer and the silicide layer, the dielectric layer having a plurality of contacts; and a patterned metal layer on the dielectric layer for contacting the active circuit and the patterned silicide layer via the contacts; wherein the patterned metal layer is separated into a first part, a second part, and a third part, and the second part is between the first part and the third part, where the first part of patterned metal layer contacts the patterned silicide layer on the first part of the patterned poly-silicon layer, the third part of patterned metal layer contacts the patterned silicide layer on the second part of the patterned poly-silicon layer, and the second part of patterned metal layer contacts both the patterned silicide layer on the first part and second part of the patterned poly-silicon layer.

According to another embodiment, the semiconductor structure of an I/O buffer comprises: a substrate; an active circuit, formed on the substrate; a silicon oxide layer on the substrate; a patterned poly-silicon layer on the silicon oxide layer; a patterned silicide layer on the patterned poly-silicon layer to expose at least part of the patterned poly-silicon layer and separated in at least two parts; a dielectric layer on the patterned poly-silicon layer and the silicide layer, the dielectric layer having a plurality of contacts; and a patterned metal layer on the dielectric layer for contacting the active circuit and the patterned silicide layer via the contacts; wherein the patterned silicide layer is separated into a first part, a second part, and a third part, and the second part is between the first part and the third part, the patterned metal layer is separated into a first part and a second part, where the first part of patterned metal layer contacts the first part of the patterned silicide layer, and the second part of patterned metal layer contacts the third part of the patterned silicide layer.

According to above mentioned circuit and structure, the endurance of the pulling resistant device can be improved. Also, the occupied area of the I/O circuit can be decreased.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a prior art I/O buffer having an ESD protection circuit.

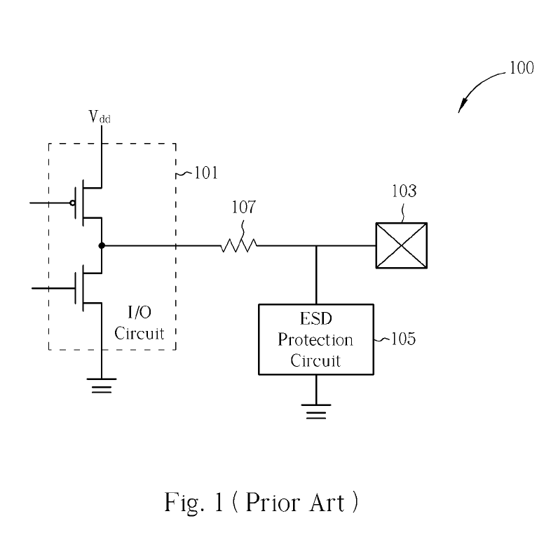

FIG. 2 is a schematic view illustrating the top view of the layout of the prior art I/O buffer having an ESD protection circuit.

FIG. 3 is a schematic diagram illustrating an I/O buffer according to an embodiment of the present invention.

FIG. 4A is a schematic diagram illustrating an I/O buffer according to another embodiment of the present invention.

FIG. 4B is a schematic diagram illustrating an I/O buffer according to another embodiment of the present invention.

FIG. 4C is a schematic diagram illustrating an I/O buffer according to another embodiment of the present invention.

FIG. 5 illustrates the top view of the layout of I/O buffers according to one embodiment of the present invention.

FIG. 6 illustrates the top view of the layout of I/O buffers according to another embodiment of the present invention.

FIG. 7 is a cross-section view illustrating a semiconductor structure corresponding to the layout shown in FIG. 5.

FIG. 8 is a cross-section view illustrating a semiconductor structure corresponding to the layout shown in FIG. 6.

### DETAILED DESCRIPTION

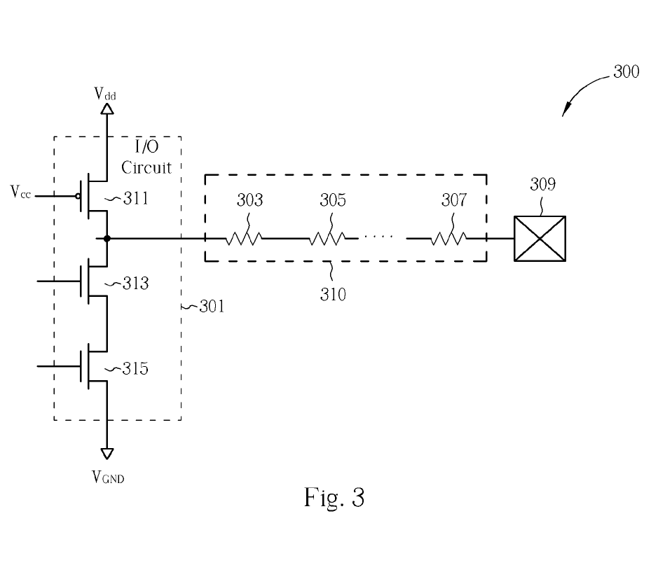

FIG. 3 is a schematic diagram illustrating an I/O buffer 300 according to an embodiment of the present invention. As shown in FIG. 3, the I/O buffer 300 comprises an I/O circuit 301, a pulling resistant device 310, and a pad 309. The I/O circuit 301 is used for inputting or outputting a signal. The pulling resistant device 310 has a plurality of resistant elements, e.g. resistors 303˜307 electrically connected in series, and the resistors 303˜307 form a resistance value R.

Since the resistance value R is created through the resistors 303˜307 (for example, N=4 resistant elements), each of the resistors 303˜307 will suffer lower individual power dissipation (as from the equation

$$P = {I}^{2} \frac{R}{N} ) ,$$

and thus the resistors 303˜307 are reduced in the likelihood of being broken. As well known by persons skilled in the art, the more number of the resistance elements is, the greater the area of the I/O buffer 300 occupies. However, the power that each resistant element decreases as the number thereof increases. Therefore, the value and number of the resistors 303˜307 can be varied according to different purposes and different embodiments. According to this structure, not only can the resistant elements have greater longevity, the ESD protection circuit can be selectively omitted to reduce the area the ESD protection circuit would otherwise consume.

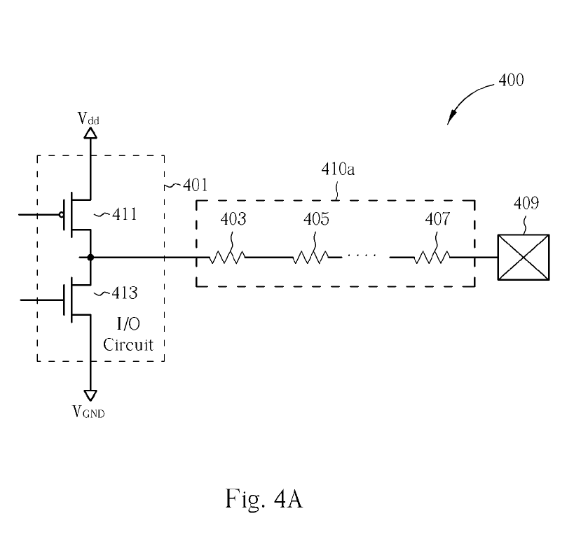

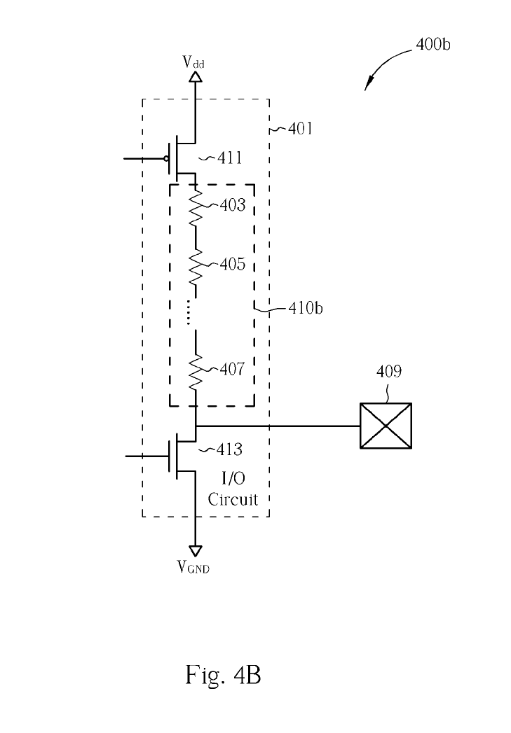

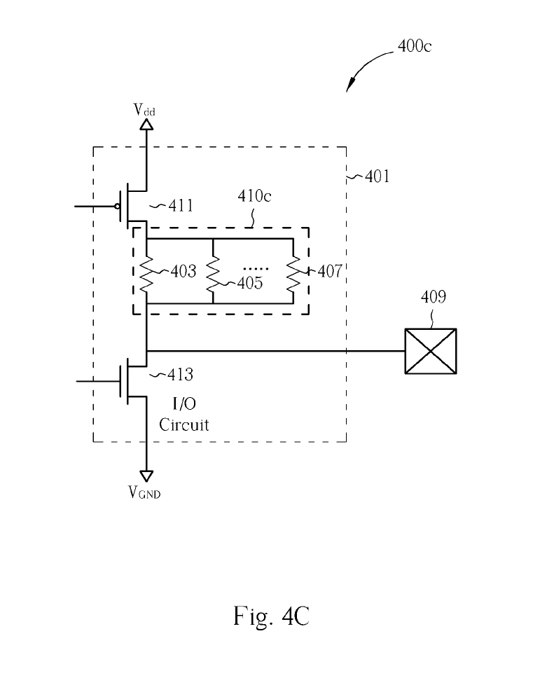

In FIG. 3 and FIGS. 4A, 4B, 4C, some examples of the I/O circuits are illustrated. These embodiments are for illustrative purposes and not intended to limit the scope of the present invention. The I/O circuit can be a high voltage tolerant I/O circuit, which comprise a PMOS transistor 311, an NMOS transistor 313 and an NMOS transistor 315, as shown in FIG. 3. The PMOS transistor 311 is coupled to a voltage level V_{dd}. The NMOS transistor 313 has a drain coupled to a drain of the PMOS transistor 311 and a gate coupled to a voltage level V_{cc}. The NMOS transistor 315 has a drain coupled to a source of the NMOS transistor 313 and a source coupled to a voltage level V_{GND}. As shown in FIG. 3, one end of the pulling resistant device 310 is directly connected to the drain of the PMOS transistor 311 and the drain of the NMOS transistor 313, while the other end of the pulling resistant device 310 is directly connected to the pad 309.

Alternatively, the I/O circuit 401 can have a PMOS transistor 411 and an NMOS transistor 413, as shown in FIG. 4A. The PMOS transistor 411 is coupled to a voltage level V_{dd}. The NMOS transistor 413 has a drain coupled to a drain of the PMOS transistor 411, and a source coupled to a voltage level V_{GND}. In this case, one end of the pulling resistant device 410a is directly connected to the drain of the PMOS transistor 411 and the drain of the NMOS transistor 413, while the other end of the pulling resistant device 410a is directly connected to the pad 409.

Alternatively, the I/O circuit 401 can have a PMOS transistor 411 and a NMOS transistor 413, as shown in FIG. 4B. The PMOS transistor 411 is coupled to a voltage level V_{dd}. In this case, one end of the pulling resistant device 410b is directly connected to the drain of the PMOS transistor 411 while the other end of the pulling resistant device 410b is connected to the drain of the NMOS transistor 413 and the pad 409.

Still alternatively, the resistant elements may be electrically connected in parallel, such as the resistors 403˜407 included in the pulling resistant device 410c, as illustrated in FIG. 4C. That is, according to the above-mentioned embodiments, the resistant elements of the pulling resistant device are segmented in space and can be electrically connected in series or in parallel according to designer's requirements.

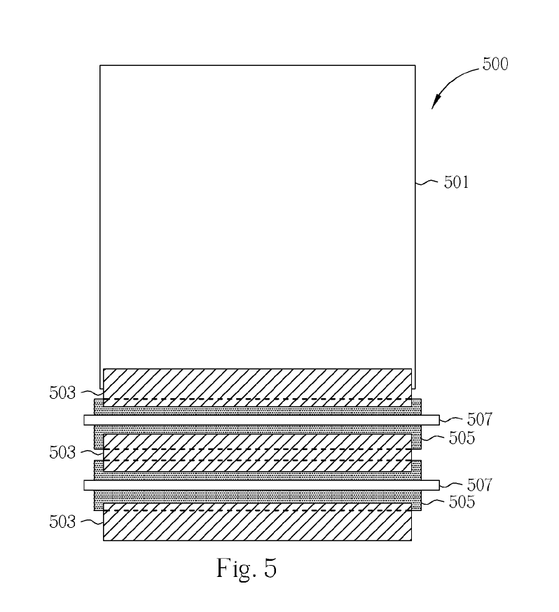

FIG. 5 illustrates the top view of the layout of I/O buffers according to one embodiments of the present invention. As shown in FIG. 5, the I/O buffer 500 includes an active circuit region 501 (for example, an I/O circuit), metal regions 503, resistor regions 505 and silicide block regions 507. The metal regions 503, resistor regions 505 and silicide block regions 507 may correspond to the pulling resistant device as illustrated in the above embodiment.

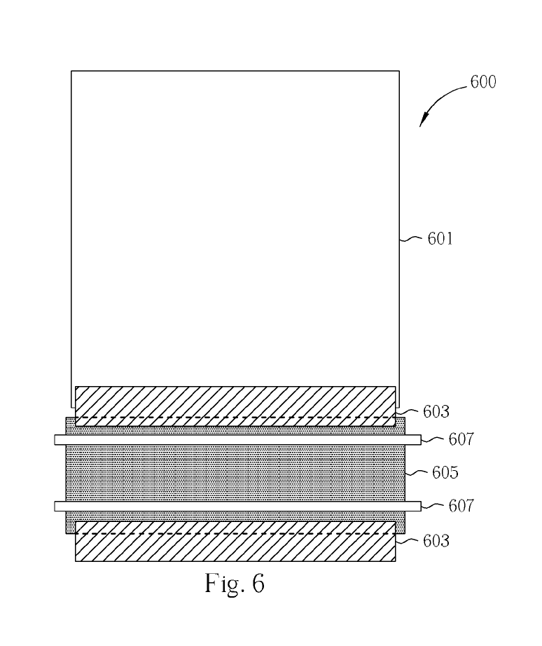

FIG. 6 illustrates the top view of the layout of I/O buffers according to another embodiment of the present invention. As shown in FIG. 6, the I/O buffer 600 includes an active circuit region 601 (for example, an I/O circuit), metal regions 603, resistor regions 605 and silicide block regions 607. The metal regions 603, resistor regions 605 and silicide block regions 607 may correspond to the pulling resistant device as illustrated in the above embodiment.

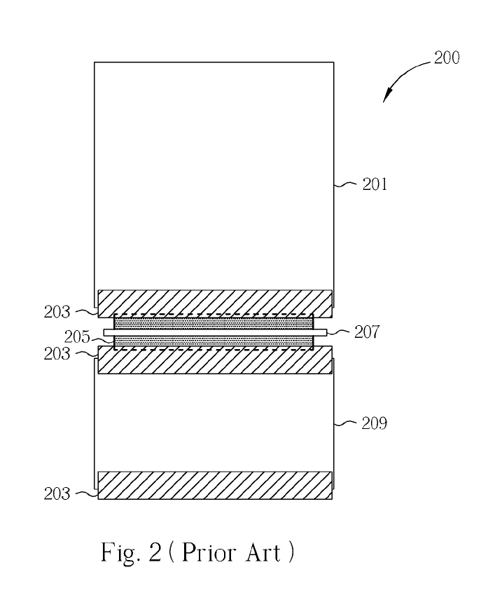

Comparing with the conventional I/O buffer 200 shown in FIG. 2, the I/O buffers shown in FIG. 5 and FIG. 6 do not have the ESD protection circuit region, allowing the total area to be decreased. Since the detail structures of FIG. 5 and FIG. 6 are well known by persons skilled in the art, thus are omitted for brevity.

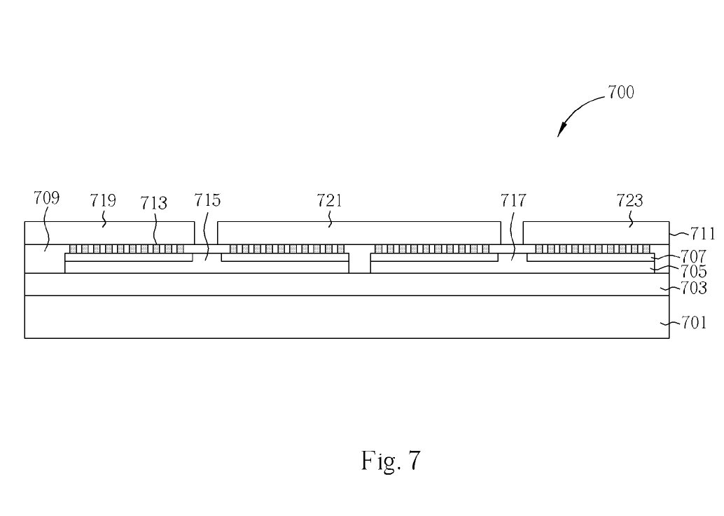

FIG. 7 is a cross-sectional view illustrating a semiconductor structure corresponding to the I/O buffer 500 shown in FIG. 5. It should be noted that, the structure of the active circuit region 501 varies in different designs, and is well known by persons skilled in the art. FIG. 7 thus only describes the semiconductor structure of the metal region 503 and the resistor region 505.

As shown in FIG. 7, the I/O buffer comprises a substrate 701 on which the active circuit (such as an I/O circuit) (not illustrated) is formed, a silicon oxide layer 703 (for example, a SiO₂ layer) on the substrate 701, a patterned poly-silicon layer 705 on the silicon oxide layer 703, a patterned silicide layer 707 on the patterned poly-silicon layer 705, a dielectric layer 709 on the patterned poly-silicon layer 705 and the patterned silicide layer 707, and a patterned metal layer 711 on the dielectric layer 709.

The patterned silicide layer 707 exposes at least part of the patterned poly-silicon layer 705. The dielectric layer 709 has a plurality of contacts 713 disposed therein. The patterned metal layer 711 is used for contacting the active circuit and the patterned silicide layer 707 via the contacts 713. As well known, the patterned poly-silicon layer 705 and the patterned silicide layer 707 form the resistant elements, such as the resistors 303˜307, 403˜407 illustrated in FIGS. 3 and 4A-4C.

The patterned poly-silicon layer 705 has a first part 715 and a second part 717, and the patterned metal layer 711 is separated into a first part 719, a second part 721, and a third part 723. The second part 721 is between the first part 719 and the third part 723. The first part 719 contacts the patterned silicide layer 707 on the first part 715 of the patterned poly-silicon layer 705, the third part 723 contacts the patterned silicide layer 707 on the second part 717, and the second part 721 of patterned metal layer 711 contacts both the patterned silicide layer 707 on the first part 715 and second part 717. In this case, the patterned poly-silicon layer 705 includes a plurality of fillisters, and the patterned silicide layer 707 is deposited on the fillisters.

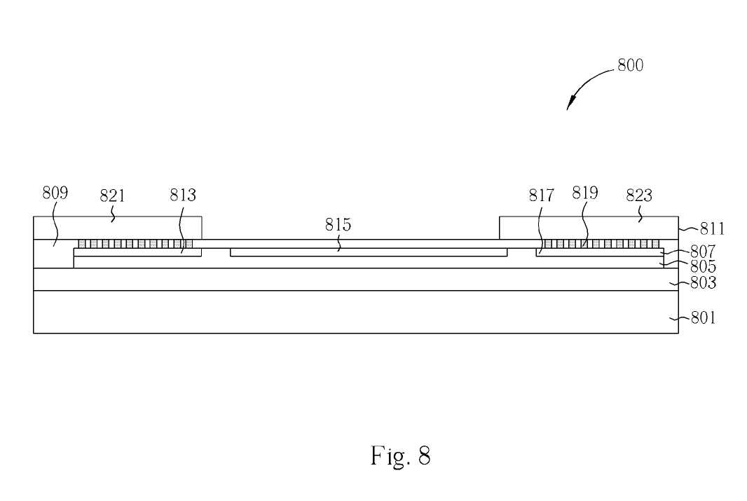

FIG. 8 is a cross-section view illustrating a semiconductor structure corresponding to the I/O buffer 600 shown in FIG. 6. Similarly, the structure of the active circuit region 601 varies with different design and is well known by persons skilled in the art, and thus FIG. 8 only describes the semiconductor structure of the metal region 603 and the resistor region 605.

As shown in FIG. 8, the I/O buffer 800 comprises a substrate 801 on which the active circuit (such as an I/O circuit) (not illustrated) is formed, a silicon oxide layer 803 (for example, a SiO₂ layer) on the substrate 801, a patterned poly-silicon layer 805 on the silicon oxide layer 803, a patterned silicide layer 807 on the patterned poly-silicon layer 805, a dielectric layer 809 on the patterned poly-silicon layer 805 and the patterned silicide layer 807, and a patterned metal layer 811 on the dielectric layer 809.

The patterned silicide layer 807 exposes at least part of the patterned poly-silicon layer 805. The dielectric layer 809 has a plurality of contacts 819 disposed therein. The patterned metal layer 811 is used for contacting the active circuit and the patterned silicide layer 807 via the contacts 819. As well known, the patterned poly-silicon layer 805 and the patterned silicide layer 807 form the resistant elements, such as the resistors 303˜307, 403˜407 illustrated in FIGS. 3 and 4A-4C.

In this case, the patterned silicide layer 807 is separated into a first part 813, a second part 815, and a third part 817. The patterned metal layer 811 is separated into a first part 821 and a second part 823. The first part 821 contacts the first part 813, and the second part 823 contacts the third part 817. The patterned poly-silicon layer 805 includes a plurality of fillisters, and the patterned silicide layer 807 is deposited on the fillisters.

According to above-mentioned circuits and structures, the longevity and lifespan of the pulling resistant device can improve. Also, the I/O buffer allows the area of the circuit to be decreased.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An I/O buffer, comprising:
an I/O circuit, for inputting or outputting a signal;
a pad; and
a pulling resistant device, having a plurality of resistant elements electrically connected between the I/O circuit and the pad, for forming a resistance value.

2. The I/O buffer of claim 1, wherein the resistant elements are electrically connected in series or in parallel.

3. The I/O buffer of claim 1, wherein resistant elements are segmented in space.

4. The I/O buffer of claim 1, wherein the I/O circuit is a high voltage tolerant I/O circuit.

5. The I/O buffer of claim 1, wherein the I/O circuit comprises a PMOS transistor and an NMOS transistor connected in series, one end of the pulling resistant device is directly connected to a drain of the PMOS transistor and a drain of the NMOS transistor, and the other end of the pulling resistant device is directly connected to the pad.

6. The I/O buffer of claim 1, wherein the I/O circuit comprises a PMOS transistor and an NMOS transistor, one end of the pulling resistant device is directly connected to a drain of the PMOS transistor, and the other end of the pulling resistant device is directly connected to a drain of the NMOS transistor.

7. A semiconductor structure of an I/O buffer, comprising:
a substrate;
an active circuit, formed on the substrate;
a silicon oxide layer on the substrate;
a patterned poly-silicon layer on the silicon oxide layer, the patterned poly-silicon layer having a first part and a second part;
a patterned silicide layer on the patterned poly-silicon layer to expose at least part of the patterned poly-silicon layer;
a dielectric layer on the patterned poly-silicon layer and the silicide layer, the dielectric layer having a plurality of contacts; and
a patterned metal layer on the dielectric layer for contacting the active circuit and the patterned silicide layer via the contacts;
wherein the patterned metal layer is separated into a first part, a second part, and a third part, and the second part is between the first part and the third part, where the first part of patterned metal layer contacts the patterned silicide layer on the first part of the patterned poly-silicon layer, the third part of patterned metal layer contacts the patterned silicide layer on the second part of the patterned poly-silicon layer, and the second part of patterned metal layer contacts both the patterned silicide layer on the first part and second part of the patterned poly-silicon layer.

8. A semiconductor structure of an I/O buffer, comprising:
a substrate;
an active circuit, formed on the substrate;
a silicon oxide layer on the substrate;
a patterned poly-silicon layer on the silicon oxide layer;
a patterned silicide layer on the patterned poly-silicon layer to expose at least part of the patterned poly-silicon layer and separated in at least two parts;
a dielectric layer on the patterned poly-silicon layer and the silicide layer, the dielectric layer having a plurality of contacts; and
a patterned metal layer on the dielectric layer for contacting the active circuit and the patterned silicide layer via the contacts;
wherein the patterned silicide layer is separated into a first part, a second part, and a third part, and the second part is between the first part and the third part, the patterned metal layer is separated into a first part and a second part, where the first part of patterned metal layer contacts the first part of the patterned silicide layer, and the second part of patterned metal layer contacts the third part of the patterned silicide layer.
